(19) United States
(12) Patent Application Publication
(10) Pub. No.: US 2023/0352280 A1
(43) Pub. Date: Nov. 2, 2023

(54) SUBSTRATE SUPPORT ASSEMBLY, SUBSTRATE SUPPORT, SUBSTRATE PROCESSING APPARATUS, AND SUBSTRATE PROCESSING METHOD

(71) Applicant: Tokyo Electron Limited, Tokyo (JP)

(72) Inventor: Yuki AHIKO, Kurokawa-gun (JP)

(73) Assignee: Tokyo Electron Limited, Tokyo (JP)

(21) Appl. No.: 18/303,485

(22) Filed: Apr. 19, 2023

(30) Foreign Application Priority Data
May 2, 2022 (JP) 2022-075991

(51) Int. Cl. H01J 37/32

(52) U.S. Cl. CPC H01J 37/32724; H01J 2237/2007; H01J 2237/334

(57) ABSTRACT

A disclosed substrate support assembly includes a substrate support, a spacer, a first base, a first thermal radiator, and a second thermal radiator. The substrate support includes an electrostatic chuck. The substrate support has a first surface and a second surface opposite to the first surface. The spacer includes a heat insulating member. The first base has a third surface facing the second surface, and supports the substrate support through the spacer between a peripheral region of the second surface and the first base. The first thermal radiator is disposed on at least a part of the second surface. The second thermal radiator is disposed on at least a part of the third surface. The first thermal radiator has a thermal emissivity higher than a thermal emissivity of the second surface. The second thermal radiator has a thermal emissivity higher than a thermal emissivity of the third surface.

### CROSS-REFERENCE TO RELATED APPLICATIONS

This application is based on and claims the benefit of priority from Japanese Patent Application No. 2022-075991 filed on May 2, 2022, the entire contents of which are incorporated herein by reference.

### FIELD

The present disclosure relates to a substrate support assembly, a substrate support, substrate processing apparatus, and a substrate processing method.

### BACKGROUND

A substrate processing apparatus is used in substrate processing such as film forming processing and etching. Japanese Unexamined Patent Publication No. 2011-192661 discloses a film forming apparatus which is a type of substrate processing apparatus. The film forming apparatus includes a mounting table provided in a chamber. The mounting table includes a base having a coolant passage and a mounting table main body including a heater. The mounting table main body is supported on the base through a heat insulating material.

### SUMMARY

In an embodiment, a substrate support assembly is provided. The substrate support assembly includes a substrate support, a spacer, a first base, a first thermal radiator, and a second thermal radiator. The substrate support includes an electrostatic chuck. The substrate support has a first surface configured to support a substrate and a second surface opposite to the first surface. The spacer includes a heat insulating member. The first base has a third surface. The third surface faces the second surface. The first base supports the substrate support through the spacer disposed between a peripheral region of the second surface and the first base. The first thermal radiator is disposed on at least a part of the second surface. The second thermal radiator is disposed on at least a part of the third surface. The first thermal radiator has a thermal emissivity higher than a thermal emissivity of the second surface of the first base. The second thermal radiator has a thermal emissivity higher than a thermal emissivity of the third surface.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a diagram for describing a configuration example of a plasma processing system.

FIG. 2 is a diagram for describing a configuration example of a capacitively coupled plasma processing apparatus.

FIG. 3 is a cross-sectional view of a substrate support assembly according to one exemplary embodiment.

FIG. 4 is an enlarged plan view of a substrate support of the substrate support assembly according to one exemplary embodiment as viewed from below.

FIG. 5 is a cross-sectional view of a substrate support assembly according to another exemplary embodiment.

FIG. 6 is a cross-sectional view of a substrate support assembly according to still another exemplary embodiment.

FIG. 7 is a cross-sectional view of a substrate support assembly according to still another exemplary embodiment.

FIG. 8 is a cross-sectional view of a substrate support assembly according to still another exemplary embodiment.

FIG. 9 is a cross-sectional view of a substrate support assembly according to still another exemplary embodiment.

FIG. 10 is a cross-sectional view of a substrate support assembly according to still another exemplary embodiment.

FIG. 11 is a cross-sectional view of a substrate support assembly according to still another exemplary embodiment.

FIG. 12 is a flowchart of a substrate processing method according to one exemplary embodiment.

### DETAILED DESCRIPTION

Hereinafter, various exemplary embodiments will be described. In the drawings, the same or corresponding parts are denoted by the same reference numerals.

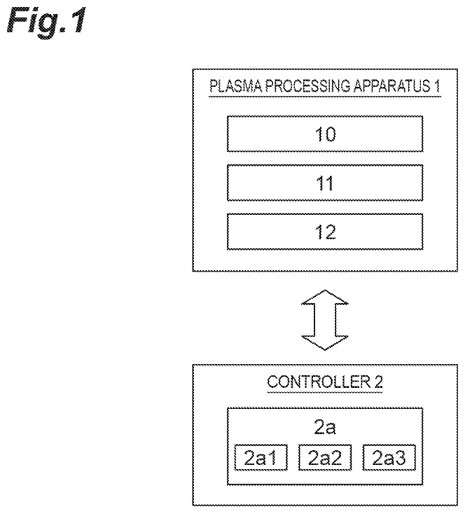

FIG. 1 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support assembly 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support assembly 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2a1, a storage 2a2, and a communication interface 2a3. The controller 2 is implemented in, for example, a computer 2a. The processor 2a1 may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2a1 reads to execute the program from the storage 2a2. The medium may be of any type which can be accessed by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

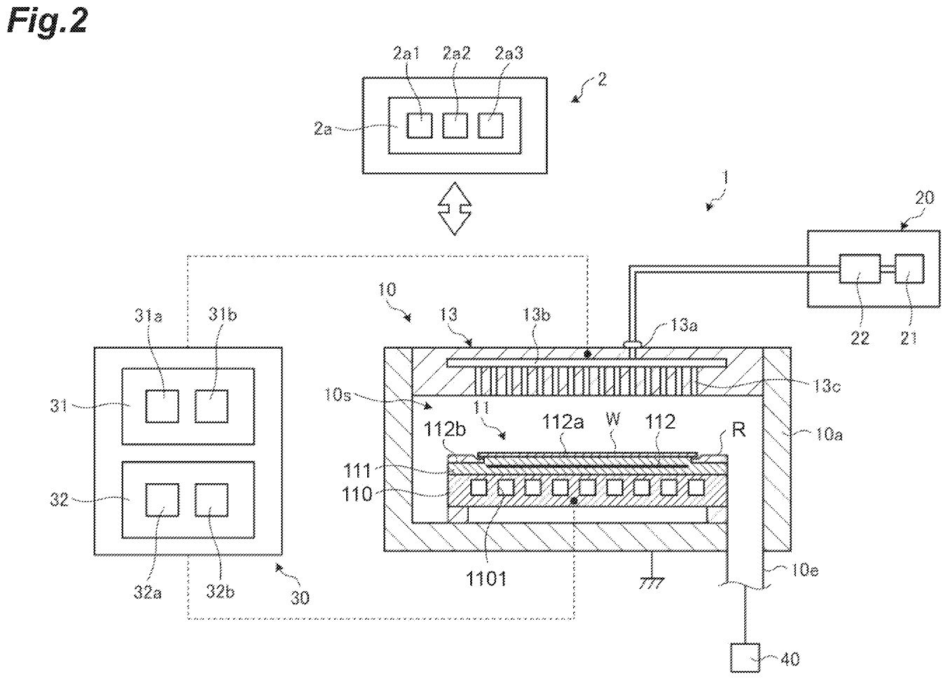

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, an electric power source 30, and a gas exhaust system 40. The plasma processing apparatus 1 further includes a substrate support assembly 11 and a gas introduction unit. The gas introduction unit is configured to introduce at least one process gas into the plasma processing chamber 10. The gas introduction unit includes a showerhead 13. The substrate support assembly 11 is disposed in a plasma processing chamber 10. The showerhead 13 is disposed above the substrate support assembly 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support assembly 11. The plasma processing chamber 10 is grounded. The showerhead 13 and the substrate support assembly 11 are electrically insulated from the housing of the plasma processing chamber 10.

The substrate support assembly 11 includes a base 110 (first base) and a substrate support 111. The substrate support 111 is supported by the base 110. The substrate support 111 includes an electrostatic chuck 112. The electrostatic chuck 112 has a surface 112a (first surface) for supporting a substrate W and a surface 112b for supporting a ring assembly R. A wafer is an example of the substrate W. The surface 112b of the electrostatic chuck 112 surrounds the surface 112a of the electrostatic chuck 112 in plan view. The substrate W is disposed on the surface 112a of the electrostatic chuck 112 and the ring assembly R is disposed on the surface 112b of the electrostatic chuck 112 to surround the substrate W on the surface 112a of the electrostatic chuck 112. Accordingly, the surface 112a is also referred to as a substrate support surface for supporting the substrate W, and the surface 112b is also referred to as a ring support surface for supporting the ring assembly R.

The ring assembly R includes one or more annular members. In an embodiment, the annular members include one or more edge rings and at least one cover ring. The edge ring is composed of a conductive or insulating material, whereas the cover ring is composed of an insulating material.

In addition, the substrate support assembly 11 may include a temperature adjusting module configured to adjust at least one of the electrostatic chuck 112, the ring assembly R, and the substrate to a target temperature. The temperature adjusting module may include one or more heater electrodes, heat transfer media, a flow passage 1101, or combinations thereof. A heat transfer fluid such as brine or gas flows through the flow passage 1101. In one embodiment, the flow passage 1101 is formed in the base 110 and one or more heater electrodes are disposed in the electrostatic chuck 112. In addition, the substrate support assembly 11 may include a heat transfer gas supply configured to supply a heat transfer gas to a gap between a rear surface of the substrate W and the surface 112a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include a flow modulation device that can modulate or pulse the flow of the at least one process gas.

The electric power source 30 include an RF source 31 coupled to the plasma processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses have rectangular, trapezoidal, or triangular waveform, or a combined waveform thereof. In an embodiment, a waveform generator for generating a sequence of voltage pulses from the DC signal is disposed between the first DC generator 32a and the at least one lower electrode. The first DC generator 32a and the waveform generator thereby functions as a voltage pulse generator. In the case that the second DC generator 32b and the waveform generator functions as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

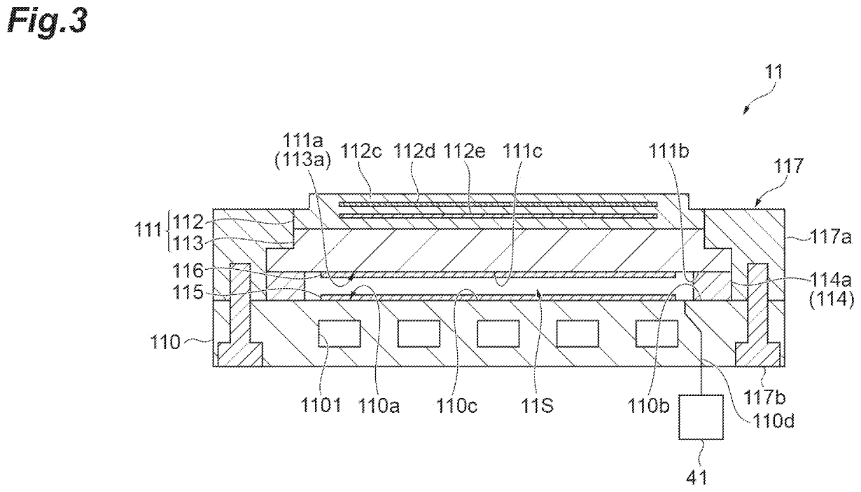

Hereinafter, the substrate support assembly according to one exemplary embodiment will be described with reference to FIG. 3. FIG. 3 is a cross-sectional view of the substrate support assembly according to one exemplary embodiment. The substrate support assembly 11 illustrated in FIG. 3 includes the base 110 (first base) and the substrate support 111 described above. The substrate support 111 is supported by the base 110.

The base 110 is made of, for example, metal. In one embodiment, the base 110 may provide the flow passage 1101 therein as described above. The flow passage 1101 receives a coolant supplied thereto. The coolant flows through the flow passage 1101.

As described above, the substrate support 111 includes the electrostatic chuck 112. The electrostatic chuck 112 includes the surface 112a (first surface) and the surface 112b as described above (see FIG. 2). The edge ring is mounted on the surface 112b. The substrate W is disposed on the surface 112a and within a region surrounded by the edge ring. The electrostatic chuck 112 includes a dielectric portion 112c and an electrostatic electrode 112d. The dielectric portion 112c is made of ceramic or resin, for example. The electrostatic electrode 112d is provided inside the dielectric portion 112c. A DC power supply or an AC power supply is electrically connected to the electrostatic electrode 112d. In one example, the DC power supply is connected to the electrostatic electrode 112d. When a voltage from the DC power supply is applied to the electrostatic electrode 112d, electrostatic attraction force is generated between the substrate W and the surface 112a. As a result, the substrate W is held by the surface 112a.

In one embodiment, the electrostatic chuck 112 may further include at least one electrode different from the electrostatic electrode 112d. At least one electrode is provided in the dielectric portion 112c. At least one electrode may include a heater electrode 112e. The heater electrode 112e is provided inside the dielectric portion 112c. The heater electrode 112e configures the temperature adjusting module described above.

In one embodiment, the substrate support 111 may further include a base 113 (second base). The base 113 configures the substrate support 111 together with the electrostatic chuck 112. The electrostatic chuck 112 is disposed on an upper surface of the base 113. The base 113 is made of, for example, metal.

The substrate support 111 includes a surface 111a (second surface). The surface 111a is a surface opposing the surface 112a. The surface 111a includes a peripheral region 111b and a central region 111c. The central region 111c is surrounded by the peripheral region 111b.

In one embodiment, the surface 111a may be a lower surface of the substrate support 111. As illustrated in FIG. 3, in the substrate support assembly 11, the surface 111a is a lower surface 113a of the base 113. The peripheral region 111b may be positioned at a periphery of the lower surface 113a. The central region 111c may be positioned in a center of the lower surface 113a.

The base 110 includes a surface 110a (third surface). The surface 110a is a surface facing the surface 111a (the second surface of the substrate support 111). The surface 110a is, for example, an upper surface of the base 110. The surface 110a includes a region 110b and a region 110c. The region 110c is surrounded by the region 110b. The region 110b may be positioned at a periphery of the surface 110a. The region 110c may be positioned in a center of the surface 110a.

The substrate support assembly 11 further includes a spacer 114. The spacer 114 includes a heat insulating member 114a. In one embodiment, the spacer 114 may include only the heat insulating member 114a. The spacer 114 is provided to separate the substrate support 111 from the base 110. The spacer 114 is positioned between the peripheral region 111b of the surface 111a and the base 110. More specifically, the spacer 114 is provided between the region 110b of the surface 110a of the base 110 and the peripheral region 111b of the surface 111a of the substrate support 111. As illustrated in FIG. 3, in the substrate support assembly 11, the heat insulating member 114a is provided between the region 110b and the peripheral region 111b to separate the substrate support 111 from the base 110. The base 110 supports the substrate support 111 through the spacer 114. The spacer 114 may have an annular shape extending along the peripheral region 111b. The spacer 114 may include a plurality of spacers disposed along the peripheral region 111b.

In one embodiment, a thermal conductivity of the heat insulating member 114a may be less than or equal to 20 W/mK. In one embodiment, the heat insulating member 114a may be made of pure titanium, 64 titanium, aluminum titanate, stainless steel, alumina, yttria, zirconia, glass ceramics, or polyimide.

In one embodiment, the substrate support 111 may be fixed to the base 110 through a fastening member 117. As illustrated in FIG. 3, in the substrate support assembly 11, the fastening member 117 includes a clamp ring 117a and a screw 117b. The screw 117b is, for example, a hexagon socket head bolt. The clamp ring 117a is fixed to the base 110 by the screw 117b. The base 110 may provide a through-hole through which the screw 117b is inserted. The screw 117b passes through the through-hole of the base 110 and is screwed into a female thread formed on a lower surface of a clamp ring 117a. Accordingly, the clamp ring 117a is fixed to the base 110. The substrate support 111 is fixed by being held between the clamp ring 117a and the base 110 through the spacer 114. The clamp ring 117a is made of metal and may constitute an electrical path for supplying an RF power and/or a first DC signal to the base 113 of the substrate support 111.

The substrate support assembly 11 further includes a thermal radiator 115 (second thermal radiator) and a thermal radiator 116 (first thermal radiator). The thermal radiator 115 is disposed on at least a part of the surface 110a. More specifically, the thermal radiator 115 is provided in at least a part of the region 110c. The thermal radiator 115 may be attached to the surface 110a. The thermal radiator 116 is disposed on at least a part of the surface 111a. More specifically, the thermal radiator 116 is provided in at least a part of the central region 111c. The thermal radiator 116 may be attached to the surface 111a. The thermal radiator 115 and the thermal radiator 116 may be provided only in portions that are likely to become a high temperature. For example, the thermal radiator 115 and the thermal radiator 116 may not be provided near the spacer 114.

The thermal radiator 115 has a thermal emissivity higher than a thermal emissivity of the surface 110a. More specifically, the thermal radiator 115 has a thermal emissivity higher than a thermal emissivity of the region 110c of the base 110. The thermal radiator 116 has a thermal emissivity higher than a thermal emissivity of the surface 111a. More specifically, the thermal radiator 116 has a thermal emissivity higher than a thermal emissivity of the central region 111c of the substrate support 111.

In one embodiment, the thermal radiator 116 may be configured to radiate heat transferred from the electrostatic chuck 112. The thermal radiator 116 has a thermal emissivity higher than a thermal emissivity of the surface 111a.

In one embodiment, each of the thermal emissivity of the thermal radiator 115 and the thermal emissivity of the thermal radiator 116 may be more than or equal to 0.7 or more than or equal to 0.9. Each of the thermal radiator 115 and the thermal radiator 116 may be a thermal radiator sheet. The thermal radiator sheet includes, for example, an aluminum sheet in which periodic fine structures are formed, a graphite sheet, a silicon sheet, or a black tape. Each of the thermal radiator 115 and the thermal radiator 116 may be applied black paint. The black paint includes, for example, SiZrO₄, Cr₂O₃, or carbon. A thermal emissivity of the graphite sheet is more than or equal to 0.9. The thermal emissivity of the black tape and the black paint is more than or equal to 0.93 and less than or equal to 0.97.

In one embodiment, a space 11s surrounded by the central region 111c of the substrate support 111, the region 110c of the base 110, and the spacer 114 may be set to a reduced pressure state, for example, a vacuum state. The space 11s may be opened to the atmosphere. As illustrated in FIG. 3, in the substrate support assembly 11, a flow passage 110d connecting the space 11s and an exhaust system 41 may be provided in the base 110. The flow passage 110d may be connected to the exhaust system 41 through the plasma processing space 10s. The exhaust system 41 may be the exhaust system 40.

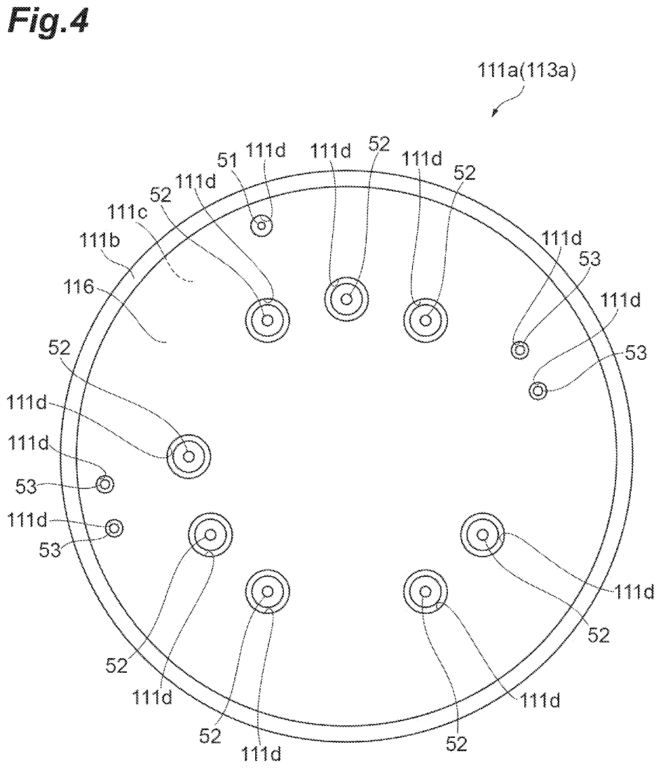

Hereinafter, reference is made to FIG. 4. FIG. 4 is an enlarged bottom view of the substrate support of the substrate support assembly according to one exemplary embodiment. In one embodiment, one or more openings 111d may be provided in the surface 111a of the substrate support 111. As an example, one or more openings 111d are a plurality of openings 111d. The thermal radiator 116 may be provided to surround each opening 111d.

For example, a terminal or a lifter pin 52 is provided in each opening 111d. The terminal includes a terminal 51 electrically connected to the electrostatic electrode 112d and a terminal 53 electrically connected to the heater electrode 112e to supply a power. The lifter pin is configured to be protruded upward from an upper surface of the electrostatic chuck 112 and retractable downward from the upper surface of the electrostatic chuck 112. An airtight member is provided at an end defining each opening 111d. Accordingly, airtightness of the space 11s is ensured with respect to each opening 111d.

In the substrate support assembly 11, since the substrate support 111 is separated from the base 110 by the spacer 114 including the heat insulating member 114a, heat exchange between the substrate support 111 and the base 110 through the spacer 114 is suppressed. It is therefore possible to set the temperature of the electrostatic chuck 112 included in the substrate support 111 to a high temperature, according to the substrate support assembly 11. In addition, heat exchange is performed between the base 110 and the substrate support 111 through the thermal radiator 115 and the thermal radiator 116. Therefore, temperature controllability of the substrate support assembly 11 is improved even in a high-temperature region, according to the substrate support assembly 11.

In the substrate support assembly 11, the plurality of openings 111d are provided in the surface 111a of the substrate support 111. The thermal radiator 116 is provided to surround each opening 111d. A portion where each opening 111d is provided is a portion where heat from the electrostatic chuck 112 is difficult to be radiated. Accordingly, the thermal radiator 116 is provided to surround each opening 111d, and thus, it is possible to control the temperature of the electrostatic chuck 112 by heat exchange even in the portion where each opening 111d is provided.

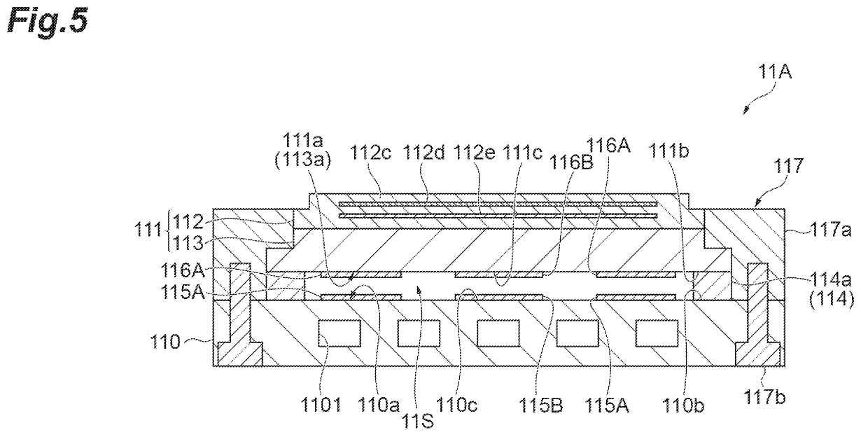

Hereinafter, reference is made to FIG. 5. FIG. 5 is a cross-sectional view of a substrate support assembly according to another exemplary embodiment. Hereinafter, a substrate support assembly 11A will be described in terms of differences between the substrate support assembly 11A according to another exemplary embodiment and the substrate support assembly 11 illustrated in FIG. 3.

As illustrated in FIG. 5, in the substrate support assembly 11A, the thermal radiator 115 is provided only in a portion or portions of the region 110c. In the substrate support assembly 11A, the thermal radiator 115 includes a thermal radiator 115A and a thermal radiator 115B. The thermal radiator 115A and the thermal radiator 115B are provided on the region 110c. The thermal radiator 115A extends closer to the region 110b than the thermal radiator 115B. The surface 110a is exposed between the thermal radiator 115A and the thermal radiator 115B.

In the substrate support assembly 11A, the thermal radiator 116 is provided only in a portion or portions of the central region 111c. In the substrate support assembly 11A, the thermal radiator 116 includes a thermal radiator 116A and a thermal radiator 116B. The thermal radiator 116A and the thermal radiator 116B are provided on the central region 111c. The thermal radiator 116A extends closer to the peripheral region 111b than the thermal radiator 116B. The surface 111a is exposed between the thermal radiator 116A and the thermal radiator 116B. It should be note that, in the substrate support assembly 11A, the flow passage 110d may not be provided in the base 110.

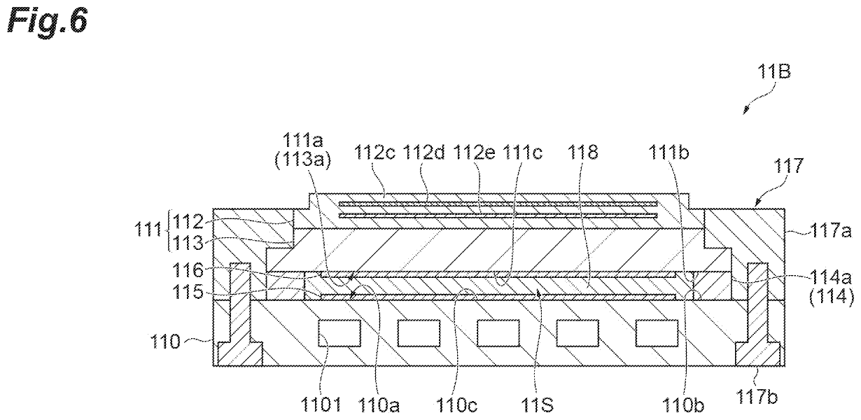

Hereinafter, reference is made to FIG. 6. FIG. 6 is a cross-sectional view of a substrate support assembly according to still another exemplary embodiment. Hereinafter, a substrate support assembly 11B will be described in terms of differences between the substrate support assembly 11B according to still another exemplary embodiment and the substrate support assembly 11 illustrated in FIG. 3.

The substrate support assembly 11B further includes an insulating member 118. The insulating member 118 is provided between the thermal radiator 115 and the thermal radiator 116. The space 11s may be filled with the insulating member 118. The insulating member 118 may have infrared transmission properties. A transmittance of infrared light having a wavelength more than or equal to 4 μm and less than or equal to 15 μm in the insulating member 118 may be more than or equal to 0.8. Such an insulating member 118 may be made of sapphire, soda glass, quartz, or resin. It should be note that, in the substrate support assembly 11B, the flow passage 110d may not be provided in the base 110.

In the substrate support assembly 11B, since the insulating member 118 is provided between the thermal radiator 115 and the thermal radiator 116, abnormal electrical discharge between the base 110 and the substrate support 111 is suppressed. Furthermore, since the infrared transmittance in the insulating member 118 is more than or equal to 0.8, heat exchange can be efficiently performed between the substrate support 111 and the base 110 through the insulating member 118.

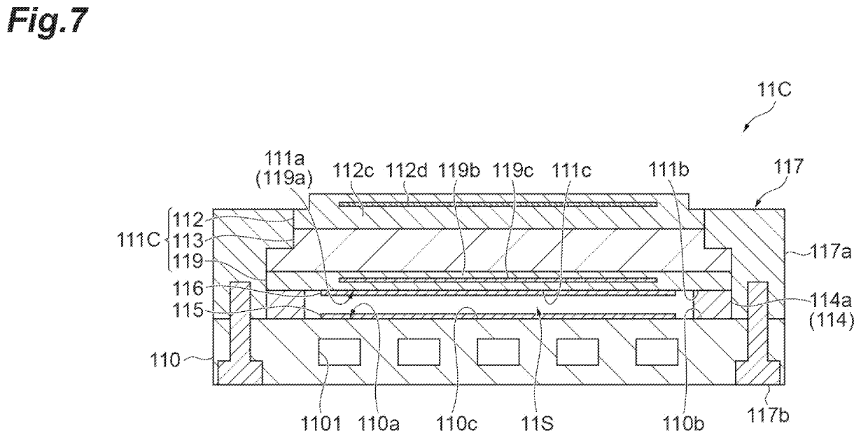

Hereinafter, reference is made to FIG. 7. FIG. 7 is a cross-sectional view of a substrate support assembly according to still another exemplary embodiment. Hereinafter, a substrate support assembly 11C will be described in terms of differences between the substrate support assembly 11C according to still another exemplary embodiment and the substrate support assembly 11 illustrated in FIG. 3.

The substrate support assembly 11C includes a substrate support 111C. The substrate support 111C further includes a temperature control unit 119 in addition to the base 113 and the electrostatic chuck 112. The temperature control unit 119 configures the temperature adjusting module described above. The base 113 is provided on the temperature control unit 119. The temperature control unit 119 is disposed under a surface opposite to the upper surface of the base 113. In the substrate support assembly 11C, the surface 111a may be a lower surface 119a of the temperature control unit 119. In the substrate support assembly 11C, the electrostatic chuck 112 does not include the heater electrode 112e. The temperature control unit 119 includes a dielectric body and a heater electrode 119c. The heater electrode 119c is provided in the dielectric body. It should be note that, in the substrate support assembly 11C, the flow passage 110d may not be provided in the base 110.

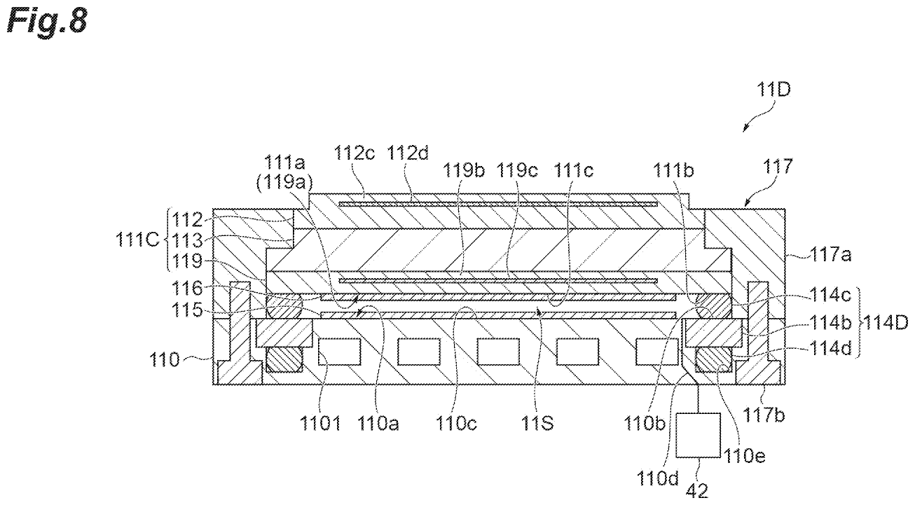

Hereinafter, reference is made to FIG. 8. FIG. 8 is a cross-sectional view of a substrate support assembly according to still another exemplary embodiment. Hereinafter, a substrate support assembly 11D will be described in terms of differences between the substrate support assembly 11D according to still another exemplary embodiment and the substrate support assembly 11C illustrated in FIG. 7.

The substrate support assembly 11D includes a spacer 114D in place of the spacer 114. The spacer 114D includes a heat insulating member 114b, a seal 114c, and a seal 114d. The heat insulating member 114b is made of the same material as the heat insulating member 114a. The seal 114c is, for example, an O-ring made of metal. The seal 114c may be a metal gasket. The seal 114d is, for example, an O-ring made of rubber. In the substrate support assembly 11D, an annular groove 110e is provided in the base 110. The seal 114d and the heat insulating member 114b are disposed within the groove 110e. The heat insulating member 114b is disposed on the seal 114d. The seal 114d is held between the base 110 and the heat insulating member 114b. The seal 114c is disposed on the heat insulating member 114b. The seal 114c is held between the peripheral region 111b and the heat insulating member 114b. That is, the seal 114c is held between the lower surface 119a of the temperature control unit 119 and the heat insulating member 114b.

The spacer 114D defines the space 11s together with the surface 110a and the surface 111a. The heat transfer fluid is supplied to the space 11s. The seal 114c seals the space 11s. For example, in the substrate support assembly 11D, the flow passage 110d connecting the space 11s to a fluid introduction system 42 is provided in the base 110. The heat transfer fluid may be a heat transfer gas. The heat transfer gas may be, for example, a noble gas or an inert gas such as a He gas or an Ar gas. The heat transfer fluid may be a heat transfer liquid. The heat transfer liquid may include, for example, silicone oil or a fluorine compound.

In the substrate support assembly 11D, since the heat transfer fluid is supplied to the space 11s, a thermal conductivity between the base 110 and the substrate support 111 is improved. Therefore, according to the substrate support assembly 11D, temperature controllability thereof is further improved.

In a substrate support assembly according to still another exemplary embodiment, the spacer 114D may have at least one partition. The partition may include a plurality of partitions. The partition divides the space 11s into a plurality of spaces. The plurality of spaces are arranged in a circumferential direction and/or a radial direction. A heat transfer fluid may be supplied to each of the plurality of spaces. A pressure of the heat transfer fluid may be independently controlled for each of the plurality of spaces. According to this substrate support assembly, since thermal conductivities of the plurality of spaces divided by the partition are independently controlled, temperature controllability thereof is further improved.

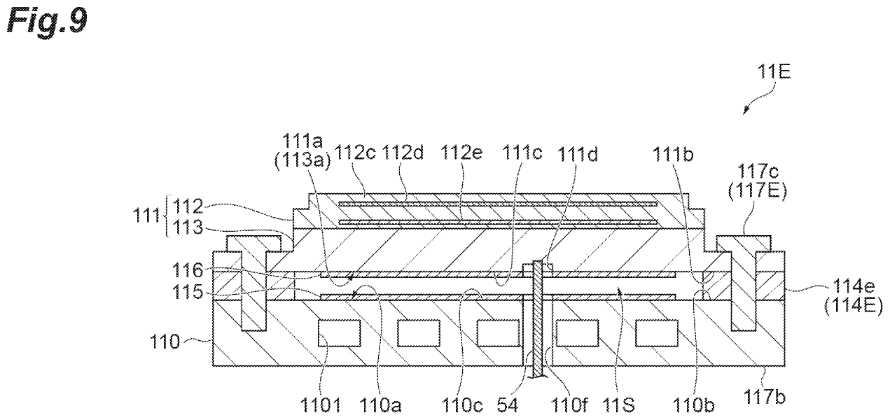

Hereinafter, reference is made to FIG. 9. FIG. 9 is a cross-sectional view of a substrate support assembly according to still another exemplary embodiment. Hereinafter, a substrate support assembly 11E will be described in terms of differences between the substrate support assembly 11E according to still another exemplary embodiment and the substrate support assembly 11 illustrated in FIG. 3.

The substrate support assembly 11E includes a spacer 114E and a fastening member 117E in place of the spacer 114 and the fastening member 117. The spacer 114E includes a heat insulating member 114e. The heat insulating member 114e is made of the same material as the heat insulating member 114a. The spacer 114E may include only the heat insulating member 114e.

The fastening member 117E does not include the clamp ring 117a. The fastening member 117E includes a screw 117c. The screw 117c is screwed into the base 110 from above the base 110 through through-holes of the substrate support 111 (base 113) and the spacer 114E. The substrate support 111 is fixed to the base 110 by being held between a head of the screw 117c and the base 110 through the spacer 114E.

The substrate support assembly 11E further includes a power feeder 54 configuring an electrical path for supplying the RF power and/or the first DC signal to the base 113. The power feeder 54 is inserted through a through-hole 110f provided by the base 110. The power feeder 54 is connected to the base 113 through a terminal provided inside the opening 111d.

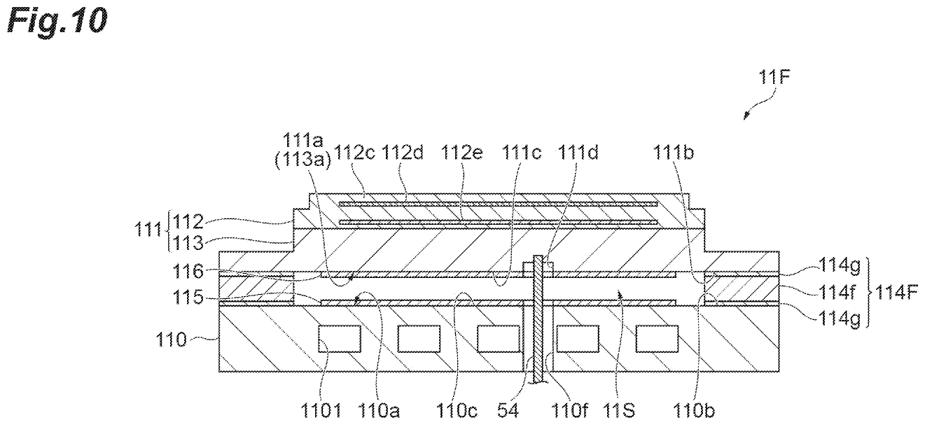

Hereinafter, reference is made to FIG. 10. FIG. 10 is a cross-sectional view of a substrate support assembly according to still another exemplary embodiment. Hereinafter, a substrate support assembly 11F will be described in terms of differences between the substrate support assembly 11F according to still another exemplary embodiment and the substrate support assembly 11E illustrated in FIG. 9.

The substrate support assembly 11E does not include the fastening member 117E. The substrate support 111 is fixed to the base without the fastening member. The substrate support assembly 11E includes a spacer 114F in place of the spacer 114E. The substrate support 111 and the spacer 114F may be fixed to each other by metal bonding. In addition, the base 110 and the spacer 114F may be fixed to each other by metal bonding. For example, the spacer 114F may include a heat insulating member 114f and bonding layers 114g respectively provided on upper and lower surfaces. The heat insulating member 114f is made of the same material as the heat insulating member 114a. Each bonding layer 114g is, for example, a brazing filler metal or a metal material for diffusion bonding.

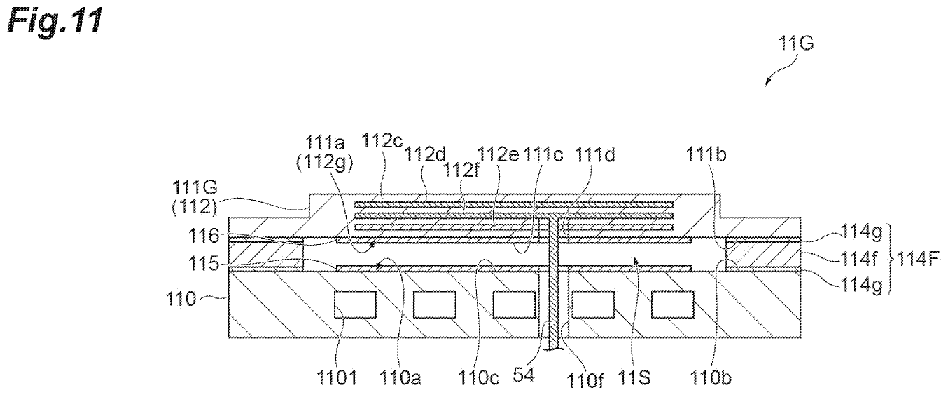

Hereinafter, reference is made to FIG. 11. FIG. 11 is a cross-sectional view of a substrate support assembly according to still another exemplary embodiment. Hereinafter, a substrate support assembly 11G will be described in terms of differences between the substrate support assembly 11G according to still another exemplary embodiment and the substrate support assembly 11F illustrated in FIG. 10.

The substrate support assembly 11G includes a substrate support 111G in place of the substrate support 111. The substrate support 111G does not include the base 113. The substrate support 111G includes the electrostatic chuck 112. In one embodiment, the electrostatic chuck 112 may include the electrostatic electrode 112d, at least one electrode, and the dielectric portion 112c. The electrostatic electrode 112d and the at least one electrode are disposed within the dielectric portion 112c. In the substrate support 111G, the surface 111a is a lower surface 112g of the dielectric portion 112c of the electrostatic chuck 112. The substrate support 111G and the spacer 114F are fixed to each other by metal bonding.

In one embodiment, the at least one electrode of the electrostatic chuck 112 may include at least one selected from the group consisting of the heater electrode, a bias electrode, and a source electrode. In the example of FIG. 11, at least one electrode of the electrostatic chuck 112 includes the heater electrode 112e and an electrode 112f. The electrode 112f may be a bias electrode and/or a source electrode. The power feeder 54 constitutes an electrical path for supplying the RF power and/or the first DC signal to the bias electrode and/or the source electrode of the electrode 112f.

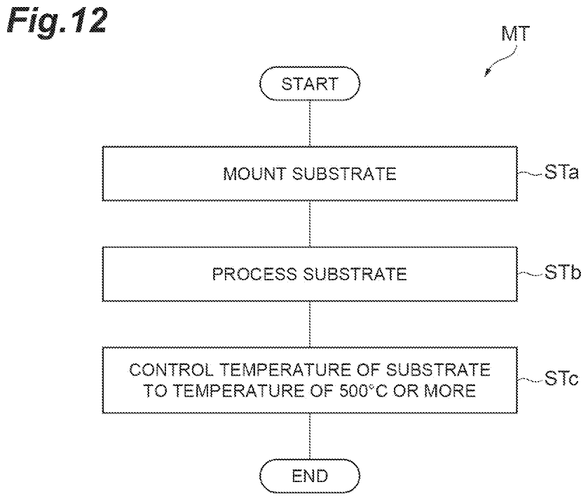

Hereinafter, a substrate processing method according to one exemplary embodiment will be described with reference to FIG. 12. FIG. 12 is a flowchart of the substrate processing method according to one exemplary embodiment. The substrate processing method (hereinafter, referred to as a “method MT”) illustrated in FIG. 12 is applied to the substrate processing apparatus. Hereinafter, the method MT will be described by taking, as an example, the case where the substrate processing apparatus is applied to the plasma processing apparatus 1. Each unit of the plasma processing apparatus 1 is controlled by the controller 2 to perform the method MT. Hereinafter, the case where the substrate W to be processed is mounted on the substrate support assembly 11 will be described as an example. It should be note that, the substrate W may be mounted on the substrate support assemblies 11A, 11B, 11C, 11D, 11E, 11F and 11G.

The method MT includes step STa and step STb. In step STa, the substrate W is mounted on the electrostatic chuck 112 of the substrate support assembly 11. For example, the substrate W is mounted on the surface 112a of the electrostatic chuck 112.

In step STb, the mounted substrate W is processed. In step STb, plasma may be generated within the plasma processing chamber 10 and the substrate W may be processed with chemical species from the plasma. The processing may be plasma processing such as plasma etching. In step STb, gas is supplied into the plasma processing chamber 10 from the gas supply 20. In addition, the exhaust system 40 also adjusts a pressure within the plasma processing chamber 10 to a designated pressure. In addition, plasma is generated from the gas in the plasma processing chamber 10 by the plasma generator 12.

The method MT further includes step STc. Step STc may be performed during execution of step STb. In step STc, a temperature of the substrate W is controlled to be more than or equal to 500° C. In step STc, the temperature of the substrate W is adjusted by the heater electrode of the substrate support assembly and/or the coolant supplied to the flow passage 1101 from a chiller unit described above.

While various exemplary embodiments have been described above, various additions, omissions, substitutions and changes may be made without being limited to the exemplary embodiments described above. Elements of the different embodiments may be combined to form another embodiment.

The thermal radiator 115 may be provided over the entire region 110c. The thermal radiator 116 may be provided in the entire central region 111c.

In addition, in another embodiment, the substrate processing apparatus may be a substrate processing apparatus other than the plasma processing apparatus 1, as long as the substrate processing apparatus includes the substrate support assembly of any of the various exemplary embodiments described above.

Here, the various exemplary embodiments included in the present disclosure are described in [E1] to [E20] below.
[E1] A substrate support assembly comprising:
a substrate support including an electrostatic chuck, the substrate support having a first surface configured to for supporting a substrate and a second surface opposite to the first surface;
a spacer including a heat insulating member;
a first base having a third surface facing the second surface, the first base supporting the substrate support through the spacer, the spacer being disposed between a peripheral region of the second surface and the first base;
a first thermal radiator disposed on at least a part of the second surface; and
a second thermal radiator disposed on at least a part of the third surface,
wherein the first thermal radiator has a thermal emissivity higher than a thermal emissivity of the second surface of the first base, and
the second thermal radiator has a thermal emissivity higher than a thermal emissivity of the third surface.
In the embodiment of [E1], since the substrate support is separated from the first base by the spacer including the heat insulating member, heat exchange between the substrate support and the first base through the spacer is suppressed. According to the above embodiment, it is therefore possible to set the temperature of the electrostatic chuck included in the substrate support to a high temperature. In addition, heat is exchanged between the first base and the substrate support through the first thermal radiator and the second thermal radiator. Therefore, the temperature controllability of the substrate support assembly is improved even in a high-temperature region, according to the above embodiment.
[E2] The substrate support assembly according to [E1] wherein each of the thermal emissivity of the first thermal radiator and the thermal emissivity of the second thermal radiator is more than or equal to 0.7 or more than or equal to 0.9.
[E3] The substrate support assembly according to [E1] or [E2], further comprising an insulating member between the first thermal radiator and the second thermal radiator, the insulating member having infrared transmission properties.
[E4] The substrate support assembly according to [E3], wherein the insulating member is made of sapphire, soda glass, quartz, or resin.
[E5] The substrate support assembly according to any one of [E1] to [E4], wherein the spacer has an annular shape extending along the peripheral region.
[E6] The substrate support assembly according to any one of [E1] to [E5], wherein the spacer, the second surface, and the third surface define a space to which a heat transfer fluid is capable to be supplied, and includes a seal that seals the space.
In the embodiment of [E6], a heat transfer fluid is supplied between the second surface and the third surface to improve thermal conductivity between the first base and the substrate support. Therefore, the temperature controllability of the substrate support assembly is further improved, according to the above embodiment.
[E7] The substrate support assembly according to [E6],
wherein the spacer further includes at least one partition that divides the space into a plurality of spaces arranged in a circumferential direction and/or a radial direction, and
a pressure of the heat transfer fluid is independently controlled for each of the plurality of spaces.
[E8] The substrate support assembly according to any one of [E1] to [E7], wherein the first base provides a flow passage to which a coolant is supplied.
[E9] The substrate support assembly according to any one of [E1] to [E8], wherein a thermal conductivity of the heat insulating member is less than or equal to 20 W/mK.
[E10] The substrate support assembly according to any one of [E1] to [E9], wherein the heat insulating member is made of pure titanium, 64 titanium, aluminum titanate, stainless steel, alumina, yttria, zirconia, glass ceramics, or polyimide.
[E11] The substrate support assembly according to any one of [E1] to [E10],
wherein one or more openings are provided in the second surface of the substrate support, and
the second thermal radiator is provided to surround the one or more openings.
[E12] The substrate support assembly according to any one of [E1] to [E11], wherein the substrate support is fixed to the first base through a fastening member.
[E13] The substrate support assembly according to any one of [E1] to [E12],
wherein the substrate support and the spacer are fixed to each other by metal bonding, and
the first base and the spacer are fixed to each other by metal bonding.
[E14] The substrate support assembly according to any one of [E1] to [E13], wherein the electrostatic chuck includes a dielectric portion, an electrostatic electrode, and at least one electrode different from the electrostatic electrode, the electrostatic electrode and the at least one electrode being disposed in the dielectric portion.
[E15] The substrate support assembly according to [E14], wherein the at least one electrode includes at least one selected from the group consisting of a heater electrode, a bias electrode, and a source electrode.
[E16] The substrate support assembly according to any one of [E1] to [E15], wherein the substrate support further includes a second base, and the electrostatic chuck is disposed on an upper surface of the second base.
[E17] The substrate support assembly according to [E16], wherein the substrate support further includes a temperature control unit including a heater electrode, the temperature control unit being disposed under a surface opposite to the upper surface of the second base.
[E18] A substrate support having a first surface configured to support a substrate and a second surface opposite to the first surface, the substrate support comprising:
an electrostatic chuck having the first surface; and
a thermal radiator disposed on at least a part of the second surface and configured to radiate heat transferred from the electrostatic chuck,
wherein the thermal radiator has a thermal emissivity higher than a thermal emissivity of the second surface.
[E19] A substrate processing apparatus comprising:
a chamber; and
the substrate support assembly according to any one of [E1] to [E17] disposed in the chamber.
[E20] A substrate processing method that is performed in the substrate processing apparatus according to [E19], the method comprising:
mounting a substrate on the electrostatic chuck of the substrate support assembly;
processing the substrate; and
controlling a temperature of the substrate to a temperature of 500° C. or more in the processing of the substrate.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the aspects following claims.

What is claimed is:

1. A substrate support assembly comprising:
a substrate support including an electrostatic chuck, the substrate support having a first surface configured to support a substrate and a second surface opposite to the first surface;
a spacer including a heat insulating member;
a first base having a third surface facing the second surface, the first base supporting the substrate support through the spacer, the spacer being disposed between a peripheral region of the second surface and the first base;
a first thermal radiator disposed on at least a part of the second surface; and
a second thermal radiator disposed on at least a part of the third surface,
wherein the first thermal radiator has a thermal emissivity higher than a thermal emissivity of the second surface of the first base, and
the second thermal radiator has a thermal emissivity higher than a thermal emissivity of the third surface.

2. The substrate support assembly according to claim 1, wherein each of the thermal emissivity of the first thermal radiator and the thermal emissivity of the second thermal radiator is more than or equal to 0.7 or more than or equal to 0.9.

3. The substrate support assembly according to claim 1, further comprising:
an insulating member between the first thermal radiator and the second thermal radiator, the insulating member having infrared transmission properties.

4. The substrate support assembly according to claim 3, wherein the insulating member is made of sapphire, soda glass, quartz, or resin.

5. The substrate support assembly according to claim 1, wherein the spacer has an annular shape extending along the peripheral region.

6. The substrate support assembly according to claim 5, wherein the spacer, the second surface, and the third surface define a space to which a heat transfer fluid is capable to be supplied, and includes a seal that seals the space.

7. The substrate support assembly according to claim 6,
wherein the spacer further includes at least one partition that divides the space into a plurality of spaces arranged in a circumferential direction and/or a radial direction, and
a pressure of the heat transfer fluid is independently controlled for each of the plurality of spaces.

8. The substrate support assembly according to claim 1, wherein the first base provides a flow passage to which a coolant is supplied.

9. The substrate support assembly according to claim 1, wherein a thermal conductivity of the heat insulating member is less than or equal to 20 W/mK.

10. The substrate support assembly according to claim 9, wherein the heat insulating member is made of pure titanium, 64 titanium, aluminum titanate, stainless steel, alumina, yttria, zirconia, glass ceramics, or polyimide.

11. The substrate support assembly according to claim 1,
wherein one or more openings are provided in the second surface of the substrate support, and
the second thermal radiator is provided to surround the one or more openings.

12. The substrate support assembly according to claim 1, wherein the substrate support is fixed to the first base through a fastening member.

13. The substrate support assembly according to claim 1,
wherein the substrate support and the spacer are fixed to each other by metal bonding, and
the first base and the spacer are fixed to each other by metal bonding.

14. The substrate support assembly according to claim 1, wherein the electrostatic chuck includes a dielectric portion, an electrostatic electrode, and at least one electrode different from the electrostatic electrode, the electrostatic electrode and the at least one electrode being disposed in the dielectric portion.

15. The substrate support assembly according to claim 14, wherein the at least one electrode includes at least one selected from the group consisting of a heater electrode, a bias electrode, and a source electrode.

16. The substrate support assembly according to claim 1, wherein the substrate support further includes a second base, and the electrostatic chuck is disposed on an upper surface of the second base.

17. The substrate support assembly according to claim 16, wherein the substrate support further includes a temperature control unit including a heater electrode, the temperature control unit being disposed under a surface opposite to the upper surface of the second base.

18. A substrate support having a first surface configured to support a substrate and a second surface opposite to the first surface, the substrate support comprising:
an electrostatic chuck having the first surface; and
a thermal radiator disposed on at least a part of the second surface and configured to radiate heat transferred from the electrostatic chuck,
wherein the thermal radiator has a thermal emissivity higher than a thermal emissivity of the second surface.

19. A substrate processing apparatus comprising:
a chamber; and
the substrate support assembly according to claim 1 disposed in the chamber.

20. A substrate processing method that is performed in the substrate processing apparatus according to claim 19, the method comprising:
mounting a substrate on the electrostatic chuck of the substrate support assembly;
processing the substrate; and
controlling a temperature of the substrate to a temperature of 500° C. or more in the processing of the substrate.
